(19) United States
(12) Patent Application Publication
(10) Pub. No.: US 2026/0079404 A1
(43) Pub. Date: Mar. 19, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventor: Yen-Chen LIN, Hsinchu City (TW)

(73) Assignee: Taiwan Semiconductor Manufacturing Company, Ltd., Hsinchu (TW)

(21) Appl. No.: 18/890,264

(22) Filed: Sep. 19, 2024

(51) Int. Cl. G03F 7/16; H01L 21/027; H01L 21/66

(52) U.S. Cl. CPC G03F 7/168; G03F 7/162; H10P 74/238; H10P 76/2041

(57) ABSTRACT

A method includes dispensing a first photoresist material onto a first substrate positioned on a substrate stage within a process chamber of a coating apparatus, wherein the process chamber is in a first exhaust rate during the dispensing the first photoresist material; measuring a thickness of the first photoresist material on the first substrate; adjusting an exhaust efficiency within the process chamber through an exhaust assembly based on the measured thickness, wherein the adjustment regulates an evacuation of air and volatiles from the process chamber; dispensing a second photoresist material onto a second substrate positioned on the substrate stage, wherein the process chamber is in a second exhaust rate during the dispensing the second photoresist material.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart illustrating a method for semiconductor manufacturing in accordance with some embodiments of the present disclosure.

FIGS. 2A-2H illustrate cross-sectional views of a wafer at various stages of fabrication in accordance with some embodiments of the present disclosure.

FIG. 3 is a block diagram of a fabrication facility in accordance with some embodiments of the present disclosure.

FIG. 4A illustrates a schematic view of a coating apparatus in accordance with some embodiments of the present disclosure.

FIG. 4B illustrates a contour map of a substrate after performing of a coating process with a coating apparatus in accordance with some embodiments of the present disclosure.

FIGS. 4C and 4D illustrate schematic views of regulators applied in a coating apparatus in accordance with some embodiments of the present disclosure.

FIG. 5A illustrates a schematic view of a baking apparatus in accordance with some embodiments of the present disclosure.

FIG. 5B illustrates a contour map of a substrate after performing of a baking process with a baking apparatus in accordance with some embodiments of the present disclosure.

FIGS. 5C-5E illustrate schematic views of an exhaust tube applied in a baking apparatus in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Photoresist (PR) profile on a substrate can ensure high-quality production of electronic components. An uneven PR profile can lead to some problems, such as inconsistent circuit patterns and potential device failure, which compromise the reliability and functionality of the semiconductor devices. Thus, maintaining a uniform thickness and shape of the photoresist across the entire wafer is essential.

To address the challenges associated with uneven PR profiles, a dynamic PR profile regulator system can be introduced, such as in the stages of coating and baking process. In some embodiments, the coater for performing the coating stage can be equipped with of exhaust pipes connected to a duct. Regulators of the dynamic PR profile regulator system can be installed in the two holes of the duct. The regulators can utilize PR profile data, acquired either from in-line monitoring or feedback mechanisms, to automatically adjust the exhaust efficiency during the coating process, allowing for the precise control of the PR application and resulting in an optimized PR profile that includes desired thickness and shape.

In some embodiments, a baking apparatus with a hot plate or a cold plate can be equipped with an exhaust pipe header including a central air exhaust tube on the upper cover, from which multiple tubes radiate outward, such as into four separate quadrants. Each quadrant can contain a tube that can be adjusted in both direction and size by 360 degrees, facilitating dynamic adjustments. This setup can allow for more targeted exhaust management, further refining the PR profile during the thermal treatment stages (e.g., baking process) of the semiconductor manufacturing process. The implementation of these dynamic PR profile regulators across both coater and hot plate can control PR thickness and shape across the substrate, ensuring each semiconductor component meets strict quality standards. Automated adjustments based on real-time data can speed up the production process and minimizing downtime.

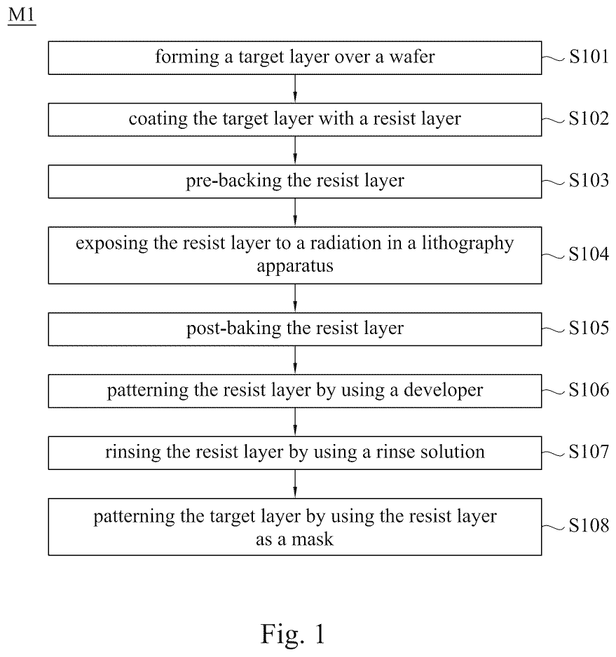

Reference is made to FIG. 1. FIG. 1 illustrates an exemplary method M1 for semiconductor manufacturing in accordance with some embodiments of the present disclosure. The method M1 includes a relevant part of the entire manufacturing process. The method M1 may be implemented, in whole or in part, by a system employing deep ultraviolet (DUV) lithography, extreme ultraviolet (EUV) lithography, electron beam (e-beam) lithography, x-ray lithography, and other appropriate lithography processes to improve pattern dimension accuracy. Additional operations can be provided before, during, and after the method M1, and some operations described can be replaced, eliminated, modified, moved around, or relocated for additional embodiments of the method. One of ordinary skill in the art may recognize other examples of semiconductor fabrication processes that may benefit from aspects of the present disclosure. The method M1 is an example, and is not intended to limit the present disclosure beyond what is explicitly recited in the claims.

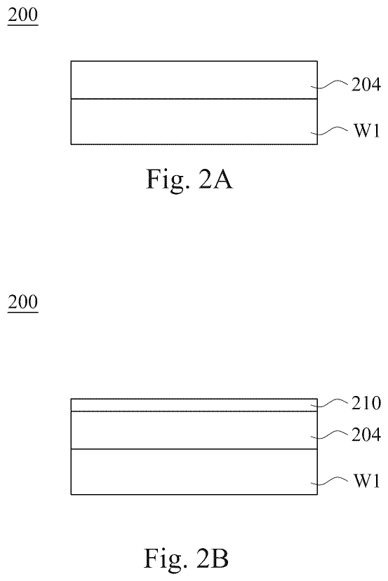

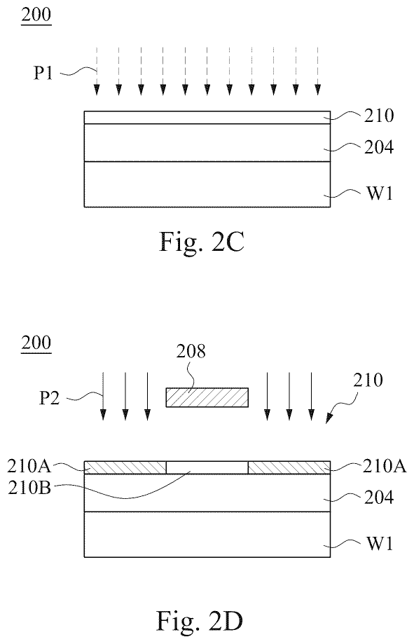

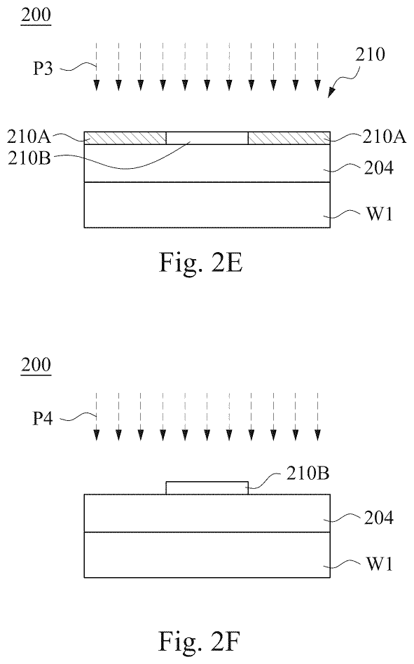

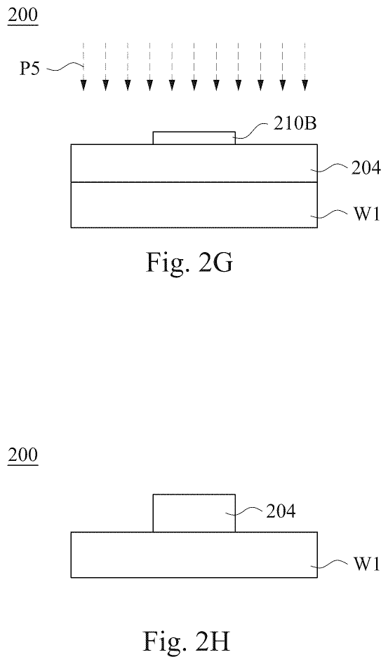

The method M1 is described below in conjunction with FIGS. 2A-2H in which a semiconductor structure 200 is fabricated by using the method M1. FIGS. 2A-2H illustrate the semiconductor structure 200 at various stages of the method M1 according to some embodiments of the present disclosure. The method M1 begins at block S101 where a target layer is formed over a wafer. Referring to FIG. 2A, in some embodiments of block S101, the wafer W1 may include one or more layers of material or composition. In some embodiments, the wafer W1 is a semiconductor substrate. In another embodiment, the wafer W1 includes silicon in a crystalline structure. In some embodiments, the wafer W1 includes other elementary semiconductors such as germanium; a compound semiconductor such as silicon carbide, gallium arsenide, indium arsenide, and indium phosphide; an alloy semiconductor such as GaAsP, AlInAs, AlGaAs, InGaAs, GaInP, and/or GaInAsP; or combinations thereof. The wafer W1 may include a silicon on insulator (SOI) substrate, be strained/stressed for performance enhancement, include epitaxial regions, include isolation regions, include doped regions, include one or more semiconductor devices or portions thereof, include conductive and/or non-conductive layers, and/or include other suitable features and layers. In some embodiments, the wafer W1 can be interchangeably referred to as a semiconductor substrate.

In some embodiments, the wafer W1 includes an epitaxial layer. For example, the wafer W1 has an epitaxial layer overlying a bulk semiconductor. In some embodiments, the wafer W1 may be a germanium-on-insulator (GOI) substrate. In some embodiments, the wafer W1 may have various device elements. Examples of device elements that are formed in the wafer W1 include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes.

A target layer 204 may be formed on the wafer W1. In some embodiments, the target layer 204 may be a hard mask layer including material(s) such as amorphous silicon (a-Si), silicon oxide, silicon nitride (SiN), titanium nitride, or other suitable material or composition. In some embodiments, the target layer 204 may include an anti-reflection coating (ARC) layer such as a nitrogen-free anti-reflection coating (NFARC) layer including material(s) such as silicon oxide, silicon oxygen carbide, or plasma enhanced chemical vapor deposited silicon oxide. In some embodiments, the target layer 204 may be formed using, for example, CVD, PVD, ALD, spin-on-glass (SOG) or other suitable techniques.

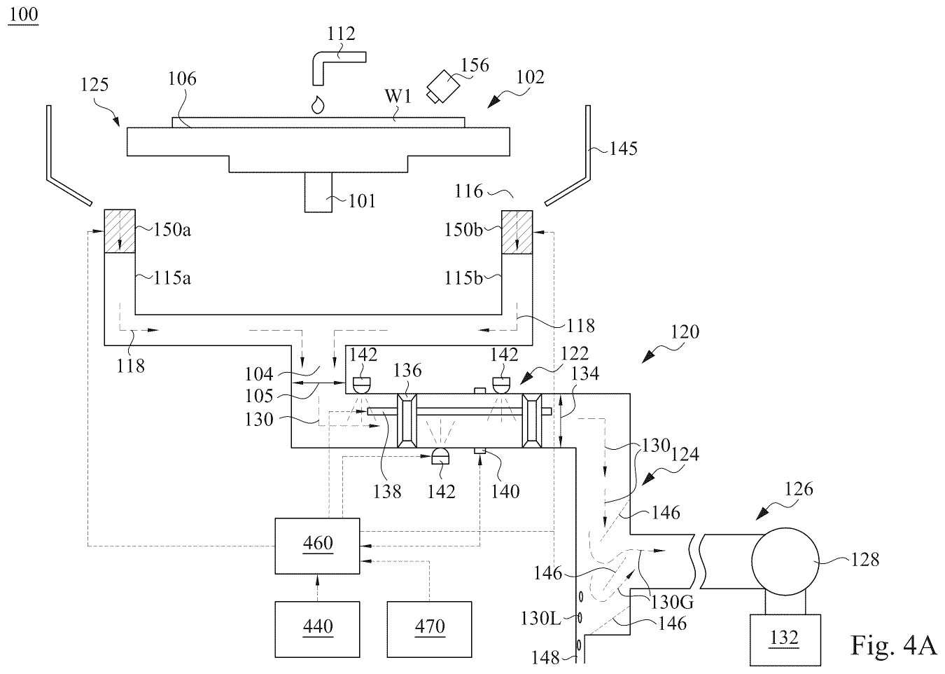

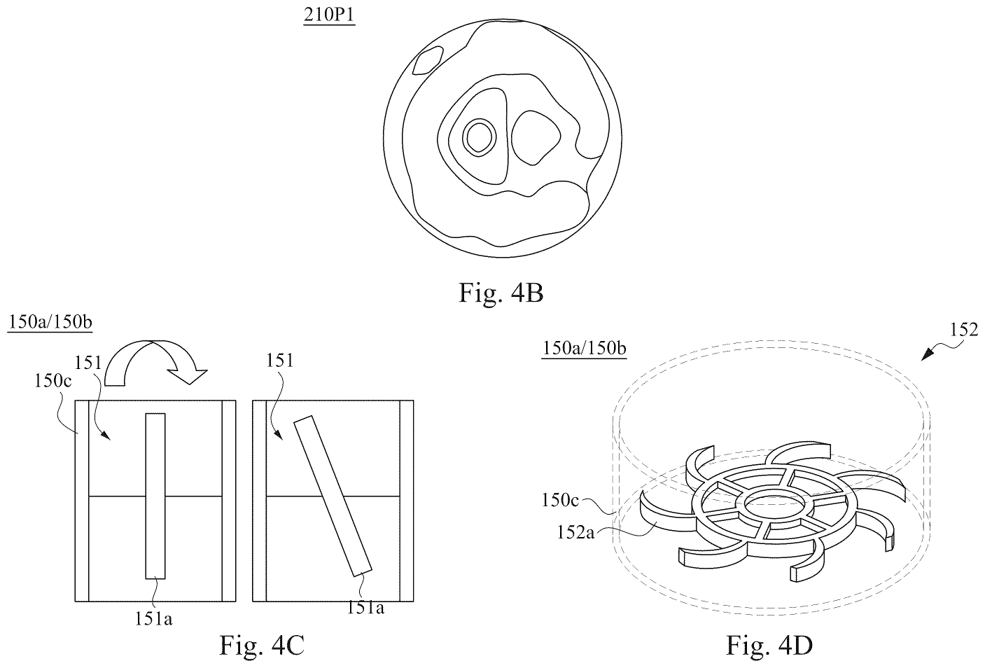

Returning to FIG. 1, the method M1 then proceeds to block S102 where the target layer is coated with a resist layer. In some embodiments of block S102, as illustrated in FIG. 2B, a resist layer 210 may be coated on the target layer 204 using a spin-on coating method through a coating apparatus (see FIG. 4A). In detail, a liquid film, such as a liquid material of the resist layer 210, can be dispensed on the wafer W1 through a dispensing nozzle in a process chamber 102 of the coating apparatus 100, and a substrate stage 106 in the process chamber 102 simultaneously rotates the wafer W1 at a rotational speed. In some embodiments, the dispensing nozzle 112 (see FIG. 4A) scans across the surface of the wafer W1 during the coating. In some embodiments, the resist layer 210 may be a deep UV photoresist. The resist layer 210 may be either a positive tone or a negative tone material, which is then exposed and developed in an aqueous base solution to form a pattern which will be transferred to the underlying target layer for defining a trench thereon in subsequent processes. It is noted that the number of layer in the resist layer 210 is exemplary. In some embodiments, the resist layer 210 may be a multi-layered structure. In some embodiments, the resist layer 210 can also be interchangeable referred to as a photoresist material. In some embodiments, the coating apparatus can also be interchangeable referred to as a coater.

In some embodiments, the cross-sectional view of the wafer W1 in FIG. 2B will be described along with the drawing shown in FIGS. 4A-4D. Some of the described stages can be replaced or eliminated in different embodiments. FIG. 4A illustrates a schematic view of a coating apparatus 100 in accordance with some embodiments of the present disclosure. FIG. 4B illustrates a profile 210p1 of the wafer W1 after performing of a coating process with the coating apparatus 100 in accordance with some embodiments of the present disclosure. FIGS. 4C and 4D illustrate schematic views of regulator 150a/150b applied in the coating apparatus 100 in accordance with some embodiments of the present disclosure.

As shown in FIG. 4A, the coating apparatus 100 includes a process chamber 102 and an exhaust assembly 120. The process chamber 102 may be any suitable semiconductor process chamber. In FIG. 4A, the process chamber 102 is a spin-coating chamber designed to coat a layer of photoresist on the wafer W1. The process chamber 102 includes a substrate stage 106 designed to retain the wafer W1 during processing. The substrate stage 106 includes a mechanism, such as a vacuum suction mechanism or other suitable mechanism, to secure the wafer W1 during operation. The substrate stage 106 can be operable to spin about a central axis 101 such that the wafer W1 secured thereon is spun during operation. A motion mechanism 110 is connected to the substrate stage 106 and operable to drive the substrate stage 106 and the wafer W1 secured thereon. In some embodiments, the motion mechanism 110 includes a motor to spin the substrate stage 106 and the wafer W1 secured thereon. In some embodiments, the motion mechanism 110 can include an elevation module to move the substrate stage 106 a vertical direction to position the wafer W1 at a lower or higher level.

The process chamber 102 includes a dispensing nozzle 112 for dispensing the resist layer 210 onto the wafer W1 secured on the substrate stage 106. During operation, the dispensing nozzle 112 dispenses the resist layer 210 on a spinning wafer W1 to coat the wafer W1 with the resist layer 210.

The exhaust assembly 120 can connect the process chamber 102 to a factory exhaust 126 through the exhaust port 104 and one or more pipe sections thereof. The exhaust assembly 120 can provide an exhaust path to remove materials, such as excess process materials and by-products, from the process chamber 102. The process chamber 102 further includes a collecting mechanism 116 to collect materials spun off the wafer W1, such as excess resist layer 210. In some embodiments, the collecting mechanism 116 includes a cup 145 to retain materials projected from the substrate stage 106. The collecting mechanism 116 can direct the collected material, such as resist layer 210, along a path 118 towards an exhaust port 104 of the process chamber 102. In some embodiments, the factory exhaust 126 includes a vacuum pump 128 to generate an exhaust flow 130 through the exhaust assembly 120. The factory exhaust 126 includes a scrubber 132 to remove hazardous materials coming from the exhaust flow 130. In some embodiments, cross sectional areas 134 of pipe sections in the exhaust assembly 120 substantially has the same dimension as a cross sectional area 105 of the exhaust port 104 to maintain exhaust capacity of the exhaust port 104.

In semiconductor manufacturing, the thickness of the resist layer 210 on wafer W1 can affect subsequent fabrication processes, and thus variations in the thickness of resist layer 210 can lead to challenges in the lithography and etching stages that follow. The coating process used to apply the resist layer 210, such as spin-coating, can result in non-uniform distribution of the material. In some embodiments, the centrifugal force during spin-coating might cause the resist layer 210 to accumulate more towards the edges of the wafer W1, potentially leading to a thicker peripheral area and a thinner central area. In some embodiments, variations in the speed of the wafer W1 during the spin-coating or inconsistencies in how the resist layer 210 is dispensed across the surface of the wafer W1 can also lead to uneven thickness. If the wafer W1 spins too quickly or too slowly, or if the dispensing nozzle 112 releases uneven amounts of resist layer 210, the final thickness can deviate from the intended measurements.

In some embodiments, the exposure process P2 (see FIG. 2D) may rely on interaction between light and the resist layer to transfer patterns from the mask (e.g., pattern 208 shown in FIG. 2D) to the wafer W1. Variations in thickness of the resist layer 210 can lead to focus issues, pattern distortions, or incomplete development of features. In some embodiments, uneven resist thickness of the resist layer 210 can also affect the etching process. Areas with thicker resist layer 210 may not etch completely, while thinner areas might be over-etched. This can lead to defects in the circuitry, such as open circuits or short circuits, which compromise the functionality of the final semiconductor device. By way of example and not limitation, if the resist layer 210 in the peripheral area of wafer W1 is consistently thicker than intended, it might not fully expose during the exposure process P2 (see FIG. 2D) due to the opacity of the thicker resist layer 210. Conversely, a thinner central area of the resist layer 210 might overexpose, causing the underlying material to be over-etched.

Therefore, the exhaust assembly 120 can be applied to control environmental conditions in the coating apparatus 100 during the coating process, affecting the drying and curing rates of the resist layer 210 on wafer W1. The exhaust assembly 120 can manage the rate at which solvents in the resist layer 210 evaporate during the coating process. Variations in exhaust efficiency (or exhaust rate) of the coating apparatus 100 can adjust the uniformity and final thickness of the resist layer 210. In some embodiment, the exhaust rate can be the speed at which air or gases are expelled from a system or space, measured in volume per unit of time (e.g., cubic feet per minute). The exhaust rate can control an environmental condition within a space, including temperature, humidity, and contaminant levels. For an exhaust pipe (e.g., exhaust pipe 115a/115b), the exhaust rate can be specifically referred to the flow rate of gases being expelled through the exhaust pipe. It can be a measure of the effectiveness of the exhaust pipe in removing or transferring gases from one environment to another, in systems where maintaining specific atmospheric conditions is necessary, such as in manufacturing processes or ventilation systems.

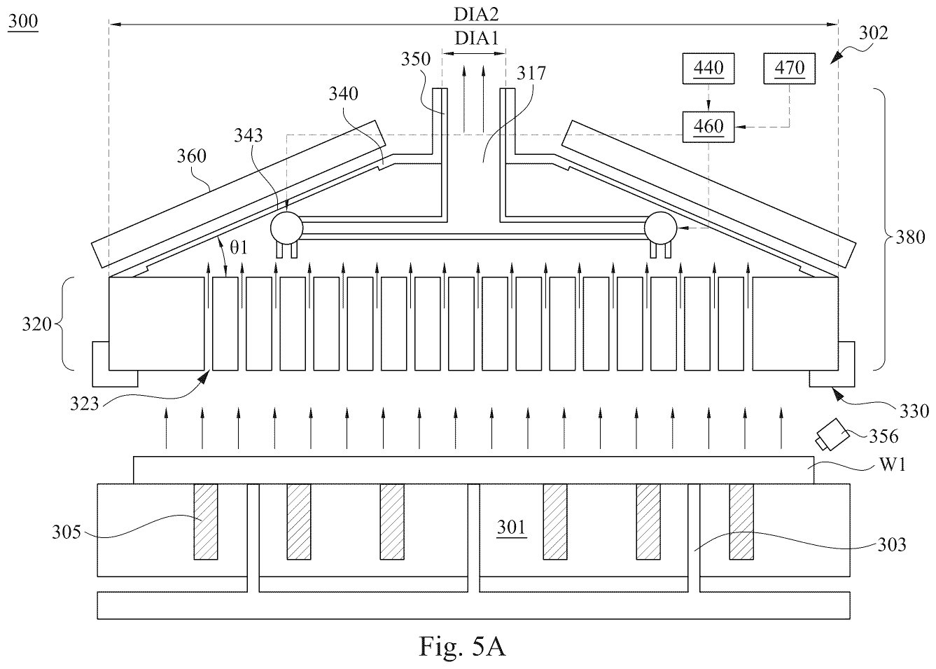

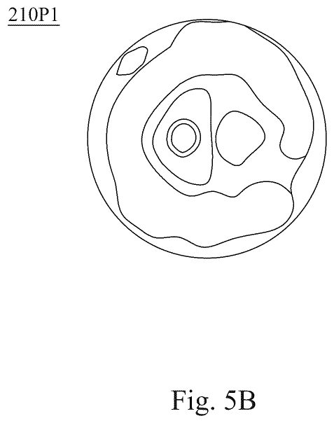

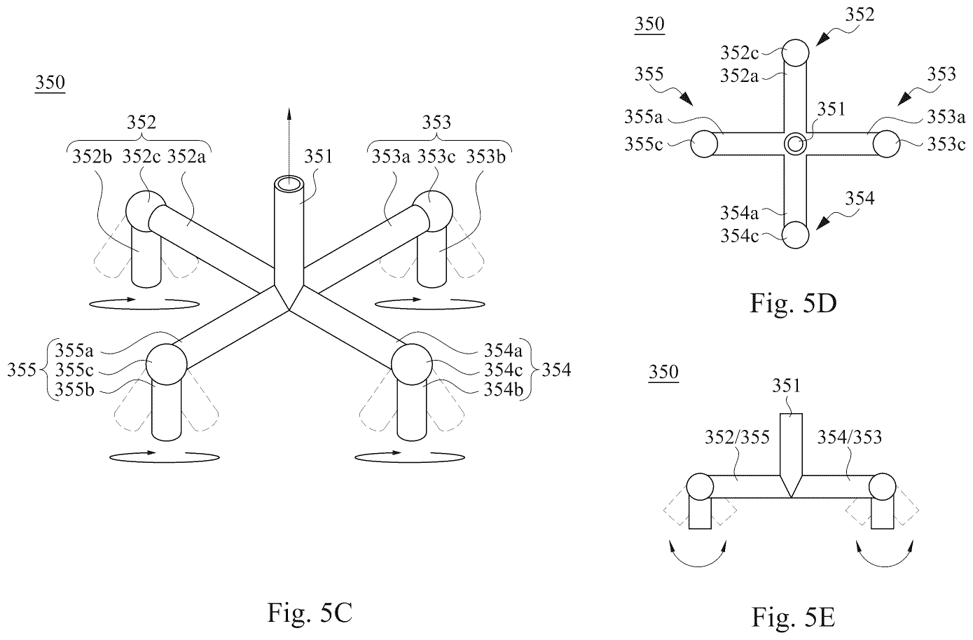

In some embodiments, the fabrication facility 1 includes a network 420 that enables various entities (a fabrication system 430, a metrology device 440, a fault detection and classification (FDC) system 450, a control system 460, an archive data base 470, and another entity 480) to communicate with one another. The network 420 may be a single network or a variety of different networks, such as an intranet, the Internet, another network, or a combination thereof. The network 420 may include wired communication channels, wireless communication channels, or a combination thereof. The FDC system 450 can evaluate conditions in the process tool (e.g., coating apparatus 100 shown in FIG. 4A and baking apparatus 300 shown in FIG. 5A), and mechanical components to detect abnormalities or faults, by monitoring the data associated the conditions in the mechanical components.

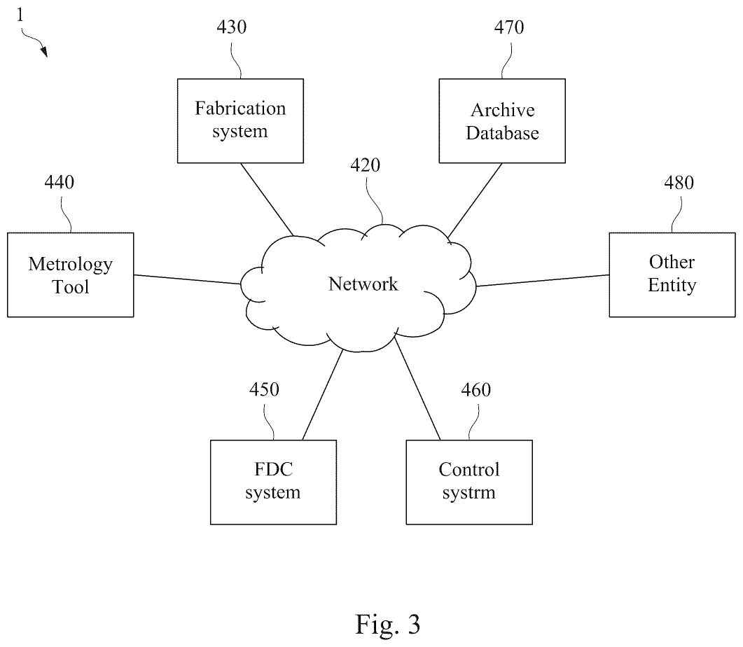

Referring back to FIG. 3, the control system 460 can implement control actions in real time. In some embodiments, the control system 460 implements control actions to control the operation status of the process tool 20 (e.g., coating apparatus 100 shown in FIG. 4A and baking apparatus 300 shown in FIG. 5A) in the fabrication system 430. In FIG. 1, the archive database 470 may include a number of storage devices to provide information storage. The information may include raw data obtained directly from the fabrication system 430 (e.g., coating apparatus 100 shown in FIG. 4A and baking apparatus 300 shown in FIG. 5A). For example, the information from coating apparatus 100 shown in FIG. 4A and baking apparatus 300 shown in FIG. 5A may be transferred to the archive database 470 and stored (or recorded) in the archive database 470 for archival purposes. The data from the process tool (e.g., coating apparatus 100 shown in FIG. 4A and baking apparatus 300 shown in FIG. 5A) may be stored in its original form (e.g., as it was obtained from the fabrication system 430) and it may be stored in its processed form (e.g., converted to a digital signal from an analog signal). The archive database 70 stores data associated with the fabrication facility 1.

In some embodiments, the archive database 470 stores data collected from the fabrication system 430, the metrology device 440, the FDC system 450, the control system 460, another entity 480, or a combination thereof. For example, the archive database 470 stores data associated with wafer characteristics of wafers processed by the fabrication system 430 (such as that collected by the metrology device 440 as described below), data associated with parameters implemented by the fabrication system 430 to process such wafers, data associated with analysis of the wafer characteristics and/or parameters of the FDC system 450 and the control system 460, and other data associated with the fabrication facility 1. In some embodiments, the fabrication system 430, the metrology device 440, the control system 460, the FDC system 450, and the other entity 480 may each have an associated database.

After the application of the resist layer 210, the metrology device 440 can be employed to assess the thickness of the resist layer 210. The metrology device 440 can utilize optical techniques to measure the reflectivity of the resist layer 210 at different points on the wafer W1. Reflectivity measurements can be influenced by the thickness of the resist layer 210; different thicknesses will reflect light differently, allowing for determinations of the profile 210p1 (see FIG. 4B) of the resist layer 210. Specifically, the metrology device 440 can send a light beam onto the surface of the resist layer 210 and capture the light that is reflected back. By analyzing the intensity and properties of the reflected light, the metrology device 440 can calculate the thickness of the resist layer 210.

Data collected by the metrology device 440 can feed into a control system 460. The control system 460 can determine if the thickness of the resist layer 210 is within acceptable ranges at various locations on the wafer W1, which can make immediate adjustments to the coating apparatus 100 or the environmental conditions to correct any detected anomalies, which in turn improves manufacturing quality. Therefore, the integration of metrology device 440 into the semiconductor manufacturing can allow for real-time quality control for promptly identifying and correcting any deviations from the desired resist thickness. In some embodiments, the control system 460 can be interchangeable referred to a controller.

Reference is made to FIGS. 3 and 4A. Enhancing the exhaust efficiency can lead to a more rapid removal of airborne solvents and other volatiles in the resist layer 210 during the coating process. This faster evacuation can promote quicker drying and curing of the resist layer 210, thereby reducing its final thickness. Conversely, lowering the exhaust efficiency can slow the removal of solvents, allowing the solvents more time to remain in liquid form on the surface of the wafer W1. This extended presence can result in a thicker deposition of the resist layer 210 as more material has time to settle before curing.

By monitoring the thickness of the resist layer 210 through the metrology device 440, adjustments can be made to the exhaust assembly 120 to correct deviations from desired thickness through the control system 460. If measurements indicate that the resist layer 210 is too thick, the exhaust efficiency can be increased for subsequent wafer. This adjustment can ensure that less solvent remains on the surface of the next wafer during the coating process, resulting in a thinner resist layer 210 on the next wafer. Conversely, if measurements indicate that the resist layer 210 is too thin, the exhaust efficiency can be reduced for subsequent wafer. The control system 460 can be configured to generate an adjustment parameter based on the captured thickness profile 210p1 of the photoresist layer 210, and initiate a modification of an operation of the regulator 150a/150b in response to the adjustment parameter. This modification can allow more solvent to linger on the surface of the next wafer during the coating process, resulting in a thicker resist layer 210 on the next wafer.

Reference is made to FIGS. 4A and 4C. The regulators 150a and 150b can be applied to adjust the exhaust rate by controlling the volume of gases that can pass through the exhaust assembly 120 during the coating process. As shown in FIG. 4C, the regulator 150a/150b can include a housing 150c. The regulators 150a and 150b can be embodied as valves 151 and the valve 151 can be laterally surrounded by the housing 150c. The regulators 150a and 150b can be installed within the exhaust pipes 115a and 115b close to the substrate stage where the resist layer 210 can be applied. In some embodiments, the exhaust pipes 115a and 115b can be connected to a duct 125. The valve 151 can operate by adjusting its flap 151a, which can change its angle relative to the cross-sectional area of the pipes 115a/115b. The positioning of the flap 151a can influence how much gas escapes from the processing environment. When the flap 151a is positioned perpendicularly to the pipe cross-section during the coating process, it maximizes the open area within the pipe, allowing a greater volume of gases to be expelled. This increase in exhaust flow accelerates the evaporation of solvents from the resist layer 210, resulting in a thinner resist layer 210. Conversely, by reducing the angle of flap 151a relative to the pipe cross-section, the open area within the pipe is diminished, which in turn limits the flow of gases, slowing down the solvent evaporation rate, resulting in a thicker resist layer 210.

Reference is made to FIGS. 4A and 4D. The regulators 150a and 150b can be embodied as fans 152, and the fan 152 can be laterally surrounded by the housing 150c. The fan 152 can operate by adjusting the rotation speed of its blades 152a, changing in the speed of the blades 152a can impact the volume of air that the fan can move, thereby controlling the exhaust rate. When the rotation speed of the blades 152a is increased, the fan 152 can enhance its capability to move air, effectively removing more gases and volatiles from the process environment. This rapid removal can increase the exhaust efficiency, leading to faster solvent evaporation from the resist layer 210. As a result, the resist can become thinner. Conversely, reducing the speed of the blades 152a can decrease the air-moving capacity of the fan 152, thus lowering the exhaust rate. This slower rate of exhaust can lead to a slower evaporation rate of the solvents in the resist layer 210, resulting in a thicker resist layer 210. In some embodiments, the installation of the regulators 150a and 150b can contributes to operational efficiency by allowing quick adjustments to be made based on real-time data from the process environment. This responsiveness can minimize downtime and enhance throughput in semiconductor production.

In some embodiments, the archive database 470 can serves as a central repository for storing records of the predetermined thickness specifications for the resist layer 210 under various process or product conditions. The archive database 470 can also archive the actual measured thicknesses (e.g., thickness profile 210p1 shown in FIG. 4B) obtained during manufacturing through the metrology device 440, allowing for historical data analysis and trend monitoring. In some embodiments, the control system 460 can access the stored data to compare the actual measured thickness of the resist layer 210 on each wafer W1 against its predetermined specifications. This comparison can help to ascertain whether the applied resist layer 210 meets the required standards. If the thickness measurement falls outside the acceptable range, the control system 460 can trigger a response. Based on the discrepancy between the measured and the predefined thickness, the control system 460 can calculates the adjustments to be made in the coating apparatus 100 to correct the thickness in subsequent wafer.

The control system 460 can modify the angle of the flap 151a in the valve 151. If the resist layer 210 is too thick, increasing the angle to allow more exhaust, thereby increasing the solvent evaporation rate of solvents to achieve a thinner resist layer 210. Conversely, if the resist layer 210 is too thin, decreasing the angle of the flap 151a in the valve 151 would reduce the exhaust rate, thereby slowing down the solvent evaporation rate to achieve a thicker resist layer 210. Similarly, the control system 460 can adjust the rotation speed of the blades 152a in the fan 152 to alter the air flow. Speeding up the fan can enhances the exhaust efficiency for thinner layers, while slowing it down can help retain more solvents, aiding in thickening the resist layer 210. This automated feedback loop can allow for real-time adjustments during the manufacturing process, enhancing the adaptability and precision of the coating operations. By dynamically adjusting the settings of the exhaust assembly 120 based on actual process outcomes, the exhaust assembly 120 can ensure consistent application of the resist layer 210 across different wafers and batches. In some embodiments, the exhaust assembly 120 can be incorporated real-time feedback from a sensor 156 that monitors solvent concentrations and environmental conditions inside the process chamber 102 of the coating apparatus 100, and the sensor 156 can be installed in the process chamber 102 and help in dynamically adjusting the exhaust efficiency.

In some embodiments, the control system 460 can independently operate the regulators 150a and 150b to fine-tune the exhaust efficiency at different locations (e.g., pipes 115a and 115b) near the substrate stage 106, allowing for specific adjustments based on real-time thickness measurements of the resist layer 210 and ensuring that each area of the wafer meets the desired specifications. By way of example and not limitation, if the resist layer 210 near the pipe 115a is detected to be thicker than desired, the control system 460 can increase the exhaust efficiency specifically at the pipe 115a by adjusting the regulator 150a. In other words, the exhaust rate after adjusting regulator 150a can be higher than the exhaust rate before adjusting regulator 150a if the measured thickness of the resist layer 210 before adjusting regulator 150a exceeds a predetermined threshold. This localized can increase in exhaust pulls away more solvent vapors, aiding in faster drying and thinning of the resist layer 210 near the pipe 115a. Conversely, if the resist layer 210 near the pipe 115a is detected to be thinner thin than desired, the control system 460 can reduce the exhaust efficiency specifically at the pipe 115b by adjusting the regulator 150b, which in turn retains more solvent near the pipe 115a, allowing the resist layer 210 to maintain a thicker profile near the pipe 115a. In other words, the exhaust rate after adjusting regulator 150a can be lower than the exhaust rate before adjusting regulator 150a if the measured thickness of the resist layer 210 before adjusting regulator 150a is below a predetermined threshold.

In scenarios where overall adjustments are needed across the wafer, the control system 460 can simultaneously activate both regulators 150a and 150b. This coordinated action can either uniformly increase or decrease the exhaust efficiency, depending on the collective measurement data from the current batch of wafers. In some embodiments, the exhaust efficiencies of the pipes 115a, 115b can be substantially the same. The system also allows for differential control where the exhaust efficiency of one pipe (e.g., one of the pipes 115a, 115b) may be increased while simultaneously decreasing it for another pipe (e.g., another one of the pipes 115a, 115b) for correcting non-uniformities across the wafer surface, balancing the drying rates to achieve a more consistent resist layer 210. In some embodiments, the exhaust efficiencies of the pipes 115a, 115b can be different from each other.

Depending on the specific setup, regulators 150a and 150b may include valves 151 or fans 152. The angle of the flap 151a in the valve 151 relative to the cross-sectional area of the pipes 115a/115b can be adjusted differently for each regulator 150a/150b, allowing for precise control over how much air or gas can pass through the pipes 115a and 115b. In some embodiments, the angles of the flaps 151a on the pipes 115a and 115b can be the same as or different from each other during the coating process. By way of example and not limitation, the angle of the flap 151a on the pipe 115a can be greater than the angle of the flap 151a on the pipe 115b during the coating process.

The rotation speeds of the blades 152a in the fans 152 can be independently controlled. Differences in speed can lead to variations in exhaust flow and thus in the evaporation rates across the wafer. In some embodiments, the rotation speeds of the blades 152a in the fans 152 on the pipes 115a and 115b can be the same as or different from each other during the coating process. By way of example and not limitation, the rotation speed of the blade 152a in the fan 152 on the pipe 115a can be greater than the rotation speed of the blade 152a in the fan 152 on the pipe 115b during the coating process. Therefore, the ability to independently and simultaneously control multiple regulators 150a and 150b within the coating apparatus 100 can provide a high degree of flexibility and precision in the manufacturing process, ensuring that each wafer is processed under optimal conditions, minimizing defects and variations in resist layer thickness.

In some embodiments, the regulator 150a/150b can be equipped with both the valve 151 and the fan 152 to offer versatile control over the coting process by manipulating air flow and pressure within the pipes 115a and 115b. This dual-component system can allow for precise adjustments to the exhaust efficiency for achieving optimal thickness and uniformity of the resist layer across the wafer. The valve 151 can adjust the passage area available for air or gas to escape, while the fan 152 can influence the rate at which air is pushed through the exhaust assembly 120, and thus the valve 151 and the fan 152 can regulate the internal environment of the coating apparatus by controlling both the volume and speed of exhaust. In some embodiments, increasing both the angle of the flap 151a in the valve 151 and the rotation speed of the fan 152 can simultaneously enhance the overall exhaust efficiency when quick evaporation of solvents from the resist is required, which in turn allows for helping to thin down the resist layer 210 more rapidly. In some embodiments, reducing the angle of the flap 151a and the speed of the fan 152 can simultaneously lower the exhaust efficiency, which in turn allows for helping to thicker the resist layer 210 more rapidly. In some embodiments, increasing the angle of the flap 151a while decreasing the rotation speed of the fan 152, or vice versa, can allow for nuanced control that can address specific environmental conditions or process requirements on different parts of the wafer.

In dual-component system, the relationship between the valve 151 and the fan 152 within the regulator 150a/150b can manage the exhaust flow. By adjusting their positions relative to the substrate stage 106, the exhaust dynamics can be fine-tuned. In some embodiments, placing the valve 151 closer to the substrate stage 106 than fan 152 can allow for rapid response and precise control of exhaust rates closer to the point of application. This setup can be used for quickly adjusting to changes in solvent evaporation rates. Conversely, placing the valve 151 further from the substrate stage than fan 152 can allow for creating a more gradual and controlled modification of the exhaust flow, potentially stabilizing the effects of any adjustments over a larger area and avoiding abrupt changes that could impact the uniformity of the resist layer 210.

In some embodiments, more than two regulators, such as 3, 4, or even up to 10, can be applied to enhance the ability of the system to provide localized exhaust management across different sections of the substrate stage 106. The regulators can be even distributed around the substrate stage 106, ensuring that each segment of the wafer is subjected to similar conditions. For instance, with four regulators, they could be positioned at each quadrant to manage exhaust flows in a balanced manner.

Referring back to FIG. 4A, the exhaust assembly 120 can be capable of automatic cleaning to maintain capacity of the exhaust path. Specifically, the exhaust assembly 120 includes a pipe cleaning assembly 122. The pipe cleaning assembly 122 automatically cleans the interior of the exhaust assembly 120 to maintain the cross sectional area 134 open during operation. The pipe cleaning assembly 122 includes a residue remover 136 designed to remove materials accumulated in the exhaust assembly 120. In some embodiments, the residue remover 136 is formed from a metal or any suitable material compatible with materials in the exhaust flow 130. In some embodiments, the residue remover 136 is formed from a ferromagnetic material so that the residue remover 136 can be driven by a magnetic drive system. In some embodiments, the residue remover 136 is formed from a ferritic stainless steel, such as type 430Ti steel, type 434 steel, type 436 steel, or type 444 steel.

An actuator 138 drives the residue remover 136 to perform a cleaning operation. Alternatively, the pipe cleaning assembly 122 can be manually activated to clean the exhaust assembly 120. In some embodiments, the actuator 138 drives the residue remover 136 to perform a cleaning operation periodically. In some embodiments, the pipe cleaning assembly 122 can perform the cleaning operation upon detection of accumulated materials in the exhaust assembly 120. In some embodiments, the actuator 138 of the magnetic drive system is a magnetic track disposed along the pipe. The residue remover 136 can be coupled to the magnetic track and movable back and forth along the magnetic track. Alternatively, the actuator 138 can be other suitable drives, such as a motor drive, a hydraulic piston, or other actuators suitable for moving the residue remover 136 back and forth in the pipe.

The pipe cleaning assembly 122 can include a sensor 140. The sensor 140 is connected to a control system 460. The sensor 140 is positioned to detect accumulated materials in the exhaust assembly 120. During operation, the control system 460 receives and analyzes measurements from the sensor 140. The control system 460 sends commands to the actuator 138 to drive the residue remover 136 to perform a cleaning operation when the measurements from the sensor 140 indicates that the accumulated materials has reached a certain degree, for example, when the accumulated materials block the sensor 140 or when the sensor 140 measurement reaches a threshold level. In some embodiments, measurements from the sensor 140 can be used to determine whether it is necessary to perform a manual cleaning or other periodical maintenance. In some embodiments, the sensor 140 can be an optical sensor assembly including a light source and a light detector positioned in the line of sight of the light source. The light source and the light detector can be attached to the pipe across from an inner volume of the pipe.

In some embodiments, the pipe cleaning assembly 122 includes a dispenser 142 designed to dispense a cleaning agent, such as a solvent of the accumulated materials in the exhaust assembly 120. In some embodiments, the dispenser 142 includes one or more spray nozzles. In some embodiments, the dispenser 142 periodically dispenses a cleaning agent to assist removal of accumulated materials. In some embodiments, the periodical dispenses of the dispenser 142 are synchronized with the periodic cleaning operation of the residue remover 136 to allow the residue remover 136 to benefit from the cleaning agent. In some embodiments, the dispenser 142 is connected to the control system 460. The control system 460 can operates the dispenser 142 when the cleaning agent is desired. Even though one pipe cleaning assembly 122 is shown in the embodiment of FIG. 4A, two or more pipe cleaning assemblies 122 may be used in an exhaust assembly 120 according to process conditions, for example, when the exhaust path is long. In some embodiments, the cleaning agent sprayed by the dispenser 142 can be a suitable liquid cleaner for removing the exhaust material passing through the pipe section 202. In the situation when the exhaust material includes photoresist, the cleaning agent includes a solvent of the photoresist. For example, the cleaning agent is a solvent of the photoresist diluted with water. In some embodiments, the cleaning agent includes a solution of an organic solvent of the photoresist, for example NMP (N-methyl pyrrolidone), DMSO (dimethyl sulfoxide), acetone, or any suitable photoresist removers.

In some embodiments, the exhaust assembly 120 includes a gas-liquid separator 124 disposed downstream from the pipe cleaning assembly 122. The gas-liquid separator 124 is configured to separate gas and liquid in the exhaust flow 130 to prevent the liquid portion of the exhaust flow 130 from going to the factory exhaust 126. The gas-liquid separator 124 includes one or more deflectors 146. Each deflector 146 is positioned at an angle relative to the exhaust flow 130 to deflect the exhaust flow 130. In some embodiments, the deflector 146 is positioned at an angle 155 relative to an axial direction of the pipe section in the gas-liquid separator 124. During operation, the gas-liquid separator 124 directs a liquid portion 130L of the exhaust flow 130 towards a drain 148 while allowing a gas portion 130G of the exhaust flow 130 to flow towards the factory exhaust 126. The separation of liquid portion 130L removes a majority of materials that are burdensome or harmful to the factory exhaust 126, thus, extending exhaust power and reducing maintenance frequencies of the factory exhaust 126.

Returning to FIG. 1, the method M1 then proceeds to block S103 where the resist layer is pre-baked. In some embodiments of block S103, as illustrated in FIG. 2C, the wafer W1 may be transferred from the spin coater to the bake plates within the baking apparatus to perform a pre-baking process P1 in a baking apparatus. The pre-baking process P1 may be performed at an elevated temperature to evaporate the solvent in the resist layer 210 for time duration sufficient to cure and dry the resist layer 210.

Returning to FIG. 1, the method M1 then proceeds to block S104 where the resist layer is exposed to a radiation in a lithography system. In some embodiments of block S104, as illustrated in FIG. 2D, an exposure process P2 is performed on the resist layer 210 in a lithography system. In some embodiments, the radiation generated by the exposure process P2 may be an I-line (365 nm), a DUV radiation such as KrF excimer laser (248 nm) or ArF excimer laser (193 nm), a EUV radiation (e.g., 13.8 nm), an e-beam, an x-ray, an ion beam, or other suitable radiations. The exposure may be performed in air, in a liquid (immersion lithography), or in a vacuum (e.g., for EUV lithography and e-beam lithography). In some embodiments, the radiation generated by the exposure process P2 may be patterned with a photomask or reticle (not shown), such as a transmissive mask or a reflective mask, which may include resolution enhancement techniques such as phase-shifting and/or optical proximity correction (OPC). In some embodiments, the radiation generated by the exposure process P2 may be directly modulated with a predefined pattern, such as an IC layout, without using a photomask (maskless lithography). In some embodiments, the radiation generated by the exposure process P2 may irradiate portions 210A of the resist layer 210 according to a pattern 208, either with a mask or maskless. Specifically, the irradiated portions 210A of the resist layer 210 may be portions exposed by the pattern 208. In some embodiments, the resist layer 210 may be a positive resist and the irradiated portions 210A become soluble in a developing chemical. In some embodiments, the resist layer 210 may be a negative resist and the unexposed portions 210B become insoluble in a developing chemical.

Returning to FIG. 1, the method M1 then proceeds to block S105 where the resist layer is post-baked. In some embodiments of block S105, as illustrated in FIG. 2E, a post-baking process P3 is performed on the resist layer 210 through a temperature-controlled plate 301 in a baking apparatus (see FIG. 5A). In some embodiments, the post-bake process P3 may be used in order to assist in the generating, dispersing, and reacting of the acid/base/free radical generated from the impingement of the energy upon the photoactive compounds in the resist layer 210 during the exposure in the radiation generated by the exposure process P2 (see FIG. 2D). Such assistance can help to create or enhance chemical reactions which generate chemical differences and different polarities between the irradiated portions 210A and the unexposed portions 210B within the resist layer 210. These chemical differences results in differences in the solubility between the irradiated portions 210A and the unexposed portions 210B. In some embodiments, the temperature-controlled plate 301 can be interchangeable referred to as a template control plate. In some embodiments, the temperature-controlled plate 301 can include a heating function or cooling function based on a process requirement for the resist layer 210. Therefore, the temperature-controlled plate 301 can be a hot plate or a cold plate.

In some embodiments, the cross-sectional view of the wafer W1 in FIG. 2E will be described along with the drawing shown in FIGS. 5A-5E. Some of the described stages can be replaced or eliminated in different embodiments. FIG. 5A illustrates a schematic view of a baking apparatus 300 in accordance with some embodiments of the present disclosure. FIG. 5B illustrates a contour map of a substrate after performing of the post-bake process P3 (see FIG. 2E) with the baking apparatus 300 in accordance with some embodiments of the present disclosure. FIGS. 5C-5E illustrate schematic views of an exhaust pipe header 350 applied in the baking apparatus 300 in accordance with some embodiments of the present disclosure.

As shown in FIG. 5A, after the exposure process P2 is complete, the wafer W1 can be transferred to the baking apparatus 300. Specifically, the wafer W1 can be placed on the temperature-controlled plate 301 of the baking apparatus 300 in preparation for further processing. The temperature-controlled plate 301 can raise the temperature of the wafer W1 and resist layer 210 in order to cure and dry the resist layer 210. In some embodiments, heating elements 305 such as resistive heating elements may be located within the temperature-controlled plate 301. The heating elements 305 can raise the temperature of the temperature-controlled plate 301 during the baking processes P3. Pins 303 pass through temperature-controlled plate 301 to raise or lower wafer W1.

The baking apparatus 300 may be connected, for example, to intake pipes (not shown) in order to introduce air into the baking apparatus 300. The baking apparatus 300 may also be connected, for example, to one or more exhaust pipes and one or more dampers to assist in the evacuation and to vary a flow rate of volatile by-products of the post-baking process P3, such as components of the evaporated solvent (illustrated by the directional arrows in FIG. 5A), from the baking apparatus 300.

The curing and drying of the resist layer 210 can remove the solvent components while leaving behind the polymer resin, the PACs, cross-linking agents, and other chosen additives. In some embodiment, a post-baking process P3 may be performed at a temperature suitable to evaporate the solvent(s), such as between about 40° C. and 150° C., although the precise temperature depends at least in part upon the materials chosen for the resist layer 210. The post-baking process P3 can be performed for a time sufficient to cure and dry the resist layer 210, such as between about 10 seconds to about 10 minutes, such as about 90 seconds. As the solvent evaporates during the post-baking process P3, the vapor of the evaporated solvent rises (as illustrated in FIG. 5A by the directional arrows) and ultimately escapes through the trench plate 320 and through the exhaust hood assembly 380.

In some embodiments, the exhaust hood assembly 380 can secure and suspend the trench plate 320 over the wafer W1 during baking processes (e.g., the post-baking process P3). According to some embodiments, the exhaust hood assembly 380 can comprise a retaining ring 330, the trench plate 320, a cover plate 340, an exhaust pipe header 350, and an exhaust hood heater 360.

The retaining ring 330 can secure the trench plate 320 to the cover plate 340. According to some embodiments, the trench plate 320 is secured by the retaining ring 330 to the cover plate 340 using fasteners (e.g., screws, threaded bolts, and the like). However, any suitable fasteners and/or any suitable way to secure the trench plate 320 between the retaining ring 330 and the cover plate 340 (e.g., clamping, snap-fitting, and the like) may also be used.

In some embodiments, the trench plate 320 comprises ridges 321, and vent holes 323. According to some embodiments, the trench plate 320 (e.g., vented cover disk) is annular in shape (e.g., a circular plate, a disk, or the like) having a second diameter DIA2 of between about 180 mm and about 320 mm. However, any suitable shape and any suitable diameter may be used for the trench plate 320. In some embodiments, the bottom surface of the trench plate 320 is substantially planar (within the range of manufacturing deviation); however, any suitable shape may be used. During baking processes (e.g., the post-baking process P3), as vapor forms and rises from the evaporated solvent, the vapor escapes through the vent holes 323 of the trench plate 320 and makes its way up towards the cover plate 340.

According to embodiments, the vent holes 323 are located in the ridges 321 and extend through the ridges 321 and the trench plate 320 from the top of the ridges 321 to the bottom surface of the trench plate 320 opposite the top surfaces of the ridges 321. According to some embodiments, the vent holes 323 are aligned radially along centerlines. In some embodiments, the vent holes 323 have the same size diameters. According to some embodiments, the diameters of the vent holes 323 are between about 1 mm and about 20 mm. However, any suitable diameters may be utilized. In other embodiments, the vent holes 323 may have diameters of different sizes. For example, the diameters of vent holes 323 that are radially aligned may increase in size as they are located further distances from a center of the trench plate 320. For example, the diameters of the vent holes 323 may increase between about 10 mm and about 50 mm, such as about 30 mm at each step away from the center. However, any suitable increase or decrease may be utilized.

The cover plate 340 can serve as a lid covering the trench plate 320 with inner sidewalls of the cover plate 340, forming a first angle θ1 with the upper surface of the trench plate 320. According to some embodiments, the first angle θ1 is between about 30° and about 90°, such as about 90°. However, any suitable angle may be used. The cover plate 340 further comprises grooves 343 and an opening 317. During baking processes (e.g., the post-baking process P3), the inner sidewalls of the cover plate 340 and the grooves 343 located in the inner sidewalls of the cover plate 340 aid in directing the vapor escaping through vent holes 323 of the trench plate 320 to the opening 317 in the cover plate 340 where the exhaust pipe header 350 is attached. According to some embodiments, the opening 317 in the cover plate 340 comprises a first diameter DIA1 of between about 20 mm and about 40 mm, such as about 30 mm, and the exhaust pipe header 350 is sized to fit the opening 317 of the cover plate 340. However, any suitable dimensions may be used for the opening 317 of the cover plate 340 and the exhaust pipe header 350.

According to embodiments, the exhaust hood assembly 380 comprises a single pipe for the exhaust pipe header 350 attached to the opening 317 in the cover plate 340. The opening 317 and the exhaust pipe header 350 are of sufficient size to maintain a flow level and exhaust efficiency for evacuating vapor from the exhaust hood assembly 380 during bake processes. In some embodiments, the flow level may be between about 20 Pa and about 500 Pa, such as about 300 Pa. However, any suitable flow level may be utilized. According to some embodiments, the exhaust pipe header 350 comprises the same diameter or substantially the same diameter as the first diameter DIA1 and is between about 20 mm and about 40 mm, such as about 30 mm. However, any suitable diameter may be utilized.

After the post-baking process P3 in semiconductor manufacturing, the thickness of the resist layer 210 on wafer W1 can vary. In some embodiments, these variations can arise due to uneven heating temperatures across the temperature-controlled plate 301 used during the process. Specifically, the temperature-controlled plate 301 is for curing the resist by heating it to a specific temperature. However, if the temperature-controlled plate 301 does not distribute heat evenly across its surface, different areas of the wafer W1 will experience different temperatures. This discrepancy can lead to variations in how the resist layer 210 cures and dries, affecting its final thickness. In some embodiments, the edges or peripheral areas of the wafer W1 may heat differently compared to the center due to their exposure to different environmental conditions inside the baking apparatus 300. For instance, the edges of the wafer W1 might cool faster or may not receive enough heat, leading to a thicker or thinner resist layer 210 compared to the intended thickness. Similarly, the central area of the wafer W1 might have a different thickness profile, which can also deviate from the target specifications. In some embodiments, a resist layer that is too thick might not adequately expose during the lithography step, leading to incomplete pattern development. Conversely, a resist layer that is too thin might overexpose, causing the patterns to bleed or not define the features sharply.

The exhaust pipe header 350 can manage and control the environmental conditions above the wafer W1 during the post-baking process P3 for maintaining the integrity of the resist layer 210. As shown in FIG. 5C, the exhaust pipe header 350 can includes a primary vertical tube 351, from which multiple tubes 352, 353, 354, and 355, radiate outward. The vertical tube 351 can pass through the opening 317 (see FIG. 5A) in the cover plate 340, which is part of the enclosure of the baking apparatus 300, ensuring that the exhaust hood assembly 380 is tightly sealed and efficient, minimizing any leakage of contaminants into or out of the controlled environment. The tubes 352, 353, 354, and 355 can extend horizontally from the end of the vertical tube 351, allowing for a comprehensive coverage over the wafer W1, ensuring uniform extraction of gases and vapors from the process environment. The tubes 352, 353, 354, and 355 each can include a horizontal Segment (e.g., 352a, 353a, 354a, 355a), a rotatable segment (e.g., 352b, 353b, 354b, 355b), and a swivel joint (e.g., 352c, 353c, 354c, 355c). The horizontal segments 352a, 353a, 354a, and 355a can serve as the main conduits for gas flow, extending outward from the vertical tube to cover more area. In some embodiments, the horizontal segments can be interchangeable referred to horizontal tubes, and the rotatable segments can be interchangeable referred to rotatable tubes or adjustable exhaust tubes.

As shown FIG. 5C, the rotatable segments 352b, 353b, 354b, and 355b can be attached to the horizontal segments 352a, 353a, 354a, and 355a via swivel joints 352c, 353c, 354c, and 355c. The rotatable segments 352b, 353b, 354b, and 355b can rotate, allowing for adjustments in the direction of exhaust flow, which in turn allows for targeting specific areas above the wafer that may require more focused exhaust, due to localized solvent concentrations or other factors. The swivel joints 352c, 353c, 354c, and 355c can enable the rotatable segments 352b, 353b, 354b, and 355b to pivot up to 360 degrees, providing exceptional flexibility in directing the exhaust flows precisely where needed. By adjusting the orientation of the rotatable segments 352b, 353b, 354b, and 355b, the exhaust hood assembly 380 can optimize the removal of volatile compounds at different locations above the wafer. As shown in the top view in FIG. 5D, the exhaust pipe header 350 may exhibit a cross-shaped profile, enhancing the distribution of exhaust capabilities across the wafer. As shown in the side view in FIG. 5E, the arrangement between the tube 351 and the tubes 352, 354 can form an inverted T-shaped profile.

During the post-baking process P3, the positioning of the exhaust openings of the rotatable segments 352b, 353b, 354b, and 355b relative to the vent holes 323 can influence the thickness and uniformity of the resist layer 210. For example, when the exhausting opening of segment 352a aligns with one of the vent holes 323 on the trench plate 320, the exhaust hood assembly 380 can operate at a higher efficiency at this specific point. This alignment can facilitate a more effective removal of volatiles and excess gases directly from the area below the aligned vent hole 323. As a result, the resist solvent can evaporate more quickly at this spot, which can lead to a thinner formation of the resist layer 210 below this vent hole 323, which in turn helps in maintaining the desired thinness of the resist layer 210. Conversely, if the exhausting opening of segment 352a is positioned away from one of the vent holes 323, the exhaust efficiency is lower at this particular point. This misalignment can mean that solvents are not evacuated as efficiently, allowing the solvents to linger longer in the vicinity of the resist layer 210. Consequently, the slower evaporation rate of the solvents can cause the resist layer 210 in this area to be thicker, which in turn helps in maintaining the desired thinness of the resist layer 210.

After the post-baking process P3, the metrology device 440 can be employed to assess the thickness of the resist layer 210. The metrology device 440 can utilize optical techniques to measure the reflectivity of the resist layer 210 at different points on the wafer W1. Reflectivity measurements can be influenced by the thickness of the resist layer 210; different thicknesses will reflect light differently, allowing for determinations of the profile 210p2 (see FIG. 5B) of the resist layer 210. Data collected by the metrology device 440 can feed into a control system 460. The control system 460 can determine if the thickness of the resist layer 210 is within acceptable ranges at various locations on the wafer W1, which can make immediate adjustments to the baking apparatus 300 to correct any detected anomalies, which in turn improves manufacturing quality. The control system 460 can be configured to generate an adjustment parameter based on the captured thickness profile 210p2 of the photoresist layer 210, and initiate a rotation of at least one of the rotatable segment (e.g., 352b, 353b, 354b, 355b) relative to the temperature-controlled plate 301 in response to the adjustment parameter. This rotation can allow the at least one of the rotatable segment (e.g., 352b, 353b, 354b, 355b) to target an area of a photoresist layer deposited on the next wafer held on the temperature-controlled plate 301.

In some embodiments, when metrology data (see FIG. 5B) indicates that the resist layer 210 at a certain location on the wafer W1 is thicker than desired, an adjustment can be made during the subsequent processing of the next wafer. Specifically, the exhausting opening of one of the rotatable segments (e.g., segment 352b, 353b, 354b, or 355b) of the exhaust pipe header 350 can be aligned directly above the corresponding vent hole 323 that is situated over the thick part of the resist layer 210. By aligning the exhaust directly above this area, the efficiency of solvent removal from this specific location can be increased. This targeted increase in exhaust efficiency can help to thin out the resist layer 210 more effectively by accelerating the evaporation of solvents, thus reducing the thickness of the resist layer 210 in this area on the subsequent wafer.

Conversely, if the thickness at a particular location on the resist layer 210 is found to be too thin, adjustments are made to decrease the exhaust efficiency for that location during the processing of the next wafer. This can be achieved by rotating the exhausting opening of a relevant segment (e.g., segment 352b, 353b, 354b, or 355b) away from the vent hole 323 that overlays the thin part of the resist layer 210. Decreasing the exhaust efficiency at this spot can mean solvents evaporate more slowly, increasing the thickness of the resist layer at this location on the next wafer. These adjustments can be facilitated by the design of the exhaust pipe header 350, which includes rotatable segments (e.g., segment 352b, 353b, 354b, or 355b) that can be controlled to target specific areas of the wafer based on feedback from the metrology device 440.

In some embodiments, after the post-baking process P3, the archive database 470 can archive the actual measured thicknesses (e.g., thickness profile 210p2 shown in FIG. 5B) through the metrology device 440, allowing for historical data analysis and trend monitoring. In some embodiments, the control system 460 can access the stored (or recorded) data to compare the actual measured thickness of the resist layer 210 on each wafer W1 against its predetermined specifications. This comparison can help to ascertain whether the applied resist layer 210 meets the required standards. If the thickness measurement falls outside the acceptable range, the control system 460 can trigger a response. Based on the discrepancy between the measured and the predefined thickness, the control system 460 can calculates the adjustments to be made in the baking apparatus 300 to correct the thickness in subsequent wafer.

The control system 460 can modify the orientation of the rotatable segments (e.g., segment 352b, 353b, 354b, or 355b) of the exhaust pipe header 350. If the thickness is found to be outside the acceptable range, the control system 460 can be triggered to make adjustments, ensuring that deviations are corrected in subsequent batches. The control system 460 can determine which specific segment (e.g., segment 352b, 353b, 354b, or 355b) of the exhaust pipe header 350 needs adjustment. Specifically, the control system 460 can first identify which segment's position need to be adjusted based on its location relative to the area of the resist layer 210 that deviated from the thickness specifications. Subsequently, the control system 460 can calculate the optimal direction and angle of rotation for the chosen segment to modify the exhaust flow directly above the specified area of the wafer. Therefore, adjusting the exhaust flow can help either increase or decrease the drying rate of the solvent, thereby adjusting the thickness of the resist layer 210. In some embodiments, the exhaust pipe header 350 can be incorporated real-time feedback from a sensor 356 that monitors solvent concentrations and environmental conditions inside the baking chamber 302 of the baking apparatus 300, and the sensor 356 can be installed in the baking chamber 302 and help in dynamically adjusting the exhaust efficiency.

In some embodiments, the control system 460 can independently operate the tubes 352, 353, 354, and 355. In some embodiments, each of the tubes 352, 353, 354, and 355 can be aligned with one of the four quadrants of the wafer, corresponding to different parts of the resist layer 210, allowing for localized control over the exhaust flow, influencing the evaporation rates and, consequently, the curing rates of the resist within each quadrant. By way of example and not limitation, if one quadrant of the resist layer 210 is consistently thicker than desired, the control system 460 can increase the exhaust rate in that specific area to enhance solvent evaporation and thin out the resist. Specifically, the segments 352b, 353b, 354b, 355b of each tube (i.e., tube 352, 353, 354, 355) can be rotated to fine-tune the positioning of the exhaust openings, allowing the system to direct the exhaust flow more precisely, targeting areas that require specific adjustments in thickness.

Rotating the segments 352b, 353b, 354b, and 355b can optimize the angle and distance from the wafer, thus modifying the exhaust's impact on the resist layer 210. In some embodiments, the rotation of the segments 352b, 353b, 354b, 355b can mean that the distance between the exhaust openings of any two adjacent segments (e.g., segments 352b, 353b, 354b, and 355b) can be increased or decreased, which in turn balances the exhaust distribution across the wafer. By controlling each exhaust tube (e.g., tube 352, 353, 354, or 355) independently, the system can ensure that the entire surface of the wafer is treated uniformly, despite varying conditions across different parts. The ability to dynamically adjust the positioning and operation of the exhaust segments 352b, 353b, 354b, 355b can allow the exhaust pipe header 350 to adapt to real-time feedback from thickness measurements, which in turn helps in maintaining optimal conditions for each batch of wafers.

In some embodiments, the exhaust pipe header 350 can have a varying number of the radially extending tubes (e.g., tubes 352, 353, 354, and 355). By way of example and not limitation, the number of radially extending tubes can be in a range from about 2 to 20, such as about 2, 3, 4, 5, 6, 7, 8, 9, 10, 11, 12, 13,14, 15, 16, 17, 18, 19, or 20. In some embodiments, the increase in the number of the radially extending tubes allows for a more granular control over the exhaust distribution, ensuring that the entire surface of the wafer is evenly exposed to controlled environmental conditions. In embodiments where there are multiple tubes, such as four radially extending tubes (e.g., tubes 352, 353, 354, and 355), these tubes are positioned around the central tube 351 at equal intervals. From a top view, this arrangement would appear symmetrical, providing balanced exhaust coverage. This geometric distribution ensures that each quadrant of the wafer receives consistent treatment, crucial for maintaining uniform thickness and properties of the resist layer 210 across the entire wafer surface. In some embodiments, during the post-baking process P3, the exhaust pipe header 350 can allow for rotational movement of its central tube 351, which in turn allows for achieving uniform treatment across the entire surface of the wafer and maintaining consistent conditions for the resist layer 210. In some embodiments, when the central tube 351 rotates, the radial tubes 352, 353, 354, and 355 rotate in unison with it. This synchronized movement can ensures that the radial position relative to the center of the wafer remains consistent among all the extending tubes, thereby standardizing the exhaust flow across different sectors of the wafer.

In some embodiments, the apparatus used for the pre-baking process P1 (see FIG. 2C) is similar in design and function to the baking apparatus 300 utilized for the post-baking process P3. Consequently, the exhaust pipe header 350, integral to controlling environmental conditions within the baking apparatus 300 during the post-baking process, is also suitable for use in the pre-baking apparatus. This compatibility can allow for a consistent approach in managing the exhaust flow and environmental conditions across different stages of the baking process, ensuring uniformity and efficiency in the treatment of substrates during both pre-baking and post-baking.

FIG. 5A further illustrates the exhaust hood heater 360 being fixed to an outer surface of the cover plate 340. In some embodiments, the exhaust hood heater 360 may be a resistive heating element, and may comprise one or more layers of suitable resistive materials, such as mica, quartz, polyimide, silicone rubber, semiconductor heater materials, metallic alloys, ceramic materials, ceramic metals, a combination thereof, or the like. During bake processes (e.g., the post-baking process P3), the exhaust hood heater 360 heats the cover plate 340 and the exhaust pipe header 350 to suitable temperatures in order to allow the evaporated solvent escape through the trench plate 320 as a vapor. According to some embodiments, the exhaust hood heater 360 heats the cover plate 340 and the exhaust pipe header 350 to a bake temperature of between about 40° C. and 150° C., although the precise temperature depends upon the thermal characteristics of the materials chosen for the resist layer 210. As such, during bake processes, the exhaust hood heater 360 further can aid in the evacuation of the vapor from the exhaust hood assembly 380, which can increase an exhaust efficiency of the baking apparatus 300 and further minimizes the amount of residue that forms from the evaporated solvent on the inner surfaces of the cover plate 340 and the exhaust pipe header 350.

Returning to FIG. 1, the method M1 then proceeds to block S106 where the resist layer is patterned using a developing chamber. In some embodiments of block S106, as illustrated in FIG. 2F, a developing process P4 is performed to the exposed resist layer 210 on the wafer W1. The developing process P4 introduces a developing chemical to the irradiated portions 210A shown in FIG. 2E. Subsequently, the irradiated portions 210A can be removed by the developing chemical and results in portions 210B. In some embodiments, the developing chemical may be dissolved in a solvent. In one example, the developing chemical may be a positive tone developing chamber, e.g., containing tetramethylammonium hydroxide (TMAH) dissolved in an aqueous solution. In some embodiments, the developing chemical may be a negative tone developing chamber, e.g., containing n-Butyl Acetate (nBA) dissolved in an organic solvent. In some embodiments, the developing chemical can be interchangeably referred to as a developer.

Returning to FIG. 1, the method M1 then proceeds to block S107 where the resist layer is rinsed by using a rinse solution. In some embodiments of block S107, as illustrated in FIG. 2G, a rinse process P5 is performed to dispense a rinse solution onto the wafer W1. In some embodiments, the rinse solution can be any proper solvent to effectively wash away the irradiated portions 210A (see FIG. 2E) of the resist layer 210, which is reacted with the developing chemical. In some embodiments, the rinse solution may be deionized water. In some embodiments, the rinse process P5 can be in-situ performed with the developing process P4. In some embodiments, the rinse process P5 may be ex-situ performed with the developing process P4.

Returning to FIG. 1, the method M1 then proceeds to block S108 where the target layer is patterned by using the resist layer as a mask. In some embodiments of block S108, as illustrated in FIG. 2H, the target layer 204 can be patterned by using the patterned resist 210B as an etch mask, thereby transferring the pattern of the patterned resist 210B to the target layer 204. For example, the target layer 204 may be etched using a dry (plasma) etching, a wet etching, and/or other etching methods. In some embodiments, the patterned resist 210B may be partially or completely consumed during the etching of the target layer 204. In some embodiments, any remaining portion of the patterned resist 210B may be stripped off, leaving the target layer 204 over the wafer W1. The method M1 may proceed to forming a final pattern or an IC device on the target layer 204. In some embodiments, the wafer W1 may be a semiconductor substrate and the method M1 can proceed to form planar devices, such as planar FETs, fin field-effect transistors (FinFETs), or nano-FETs.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a dynamic PR profile regulator system, such as in the stages of coating and baking process. In some embodiments, the coater for performing the coating stage can be equipped with of exhaust pipes connected to a duct. Regulators of the dynamic PR profile regulator system can be installed in the two holes of the duct. The regulators can utilize PR profile data, acquired either from in-line monitoring or feedback mechanisms, to automatically adjust the exhaust efficiency during the coating process, allowing for the precise control of the PR application and resulting in an optimized PR profile that includes desired thickness and shape. In some embodiments, a baking apparatus with a hot plate or a cold plate can be equipped with an exhaust pipe header including a central air exhaust tube on the upper cover, from which multiple tubes radiate outward, such as into four separate quadrants. Each quadrant can contain a tube that can be adjusted in both direction and size by 360 degrees, facilitating dynamic adjustments. This setup can allow for more targeted exhaust management, further refining the PR profile during the thermal treatment stages (e.g., baking process) of the semiconductor manufacturing process. The implementation of these dynamic PR profile regulators across both coater and hot plate can control PR thickness and shape across the substrate, ensuring each semiconductor component meets strict quality standards. Automated adjustments based on real-time data can speed up the production process and minimizing downtime.

In some embodiments, a method includes coating a first photoresist material onto a first substrate positioned on a substrate stage within a process chamber of a coating apparatus, wherein the process chamber is in a first exhaust rate during the dispensing the first photoresist material; measuring a thickness of the first photoresist material on the first substrate; adjusting an exhaust efficiency within the process chamber through an exhaust assembly based on the measured thickness, wherein the adjustment regulates an evacuation of air and volatiles from the process chamber; coating a second photoresist material onto a second substrate positioned on the substrate stage, wherein the process chamber is in a second exhaust rate during the dispensing the second photoresist material. In some embodiments, the second exhaust rate is higher than the first exhaust rate when the measured thickness of the first photoresist material exceeds a predetermined threshold. In some embodiments, the second exhaust rate is lower than the first exhaust rate when the measured thickness of the first photoresist material is below a predetermined threshold. In some embodiments, the step of adjusting the exhaust efficiency comprises: comparing the measured thickness of the first photoresist material with a predetermined thickness; calculating the second exhaust rate from the first exhaust rate based on an outcome of the comparison. In some embodiments, the method further includes recording the measured thickness of the first photoresist material in an archive database. In some embodiments, the step of adjusting the exhaust efficiency comprises: modifying an operation of a first regulator connected to a first exhaust pipe of the exhaust assembly. In some embodiments, the first regulator comprises a first valve, and the step of adjusting the exhaust efficiency comprises setting a first valve flap of the first valve to a first orientation. In some embodiments, the method further includes modifying an operation of a second regulator connected to a second exhaust pipe of the exhaust assembly, wherein the second regulator comprises a second valve, and the step of adjusting the exhaust efficiency comprises setting a second valve flap of the second valve to a second orientation different than the first orientation. In some embodiments, the first regulator comprises a first fan, and the step of adjusting the exhaust efficiency comprises setting a first fan blade in the first fan to a first rotation speed. In some embodiments, the method further includes modifying an operation of a second regulator connected to a second exhaust pipe of the exhaust assembly, wherein the second regulator comprises a second fan, and the step of adjusting the exhaust efficiency comprises setting a second fan blade in the second fan to a second rotation speed different than the first rotation speed.

In some embodiments, a method includes positioning a first substrate on a temperature-controlled plate within a process chamber of a fabrication apparatus; curing a first photoresist layer deposited on the first substrate using the temperature-controlled plate; measuring a thickness of the cured first photoresist layer; positioning a second substrate on the temperature-controlled plate; after positioning the second substrate, adjusting an exhaust condition within the process chamber based on the measured thickness; curing a second photoresist layer deposited on the second substrate. In some embodiments, the temperature-controlled plate comprises a heating function or cooling function based on a process requirement for the first and second photoresist layers. In some embodiments, the method further includes before positioning the first substrate on the temperature-controlled plate, performing an exposure process on the first substrate, wherein the exposure process patterns the first photoresist layer deposited on the first substrate. In some embodiments, the step of adjusting the exhaust condition comprises: actuating an exhaust assembly to modify an evacuation rate of an evaporated solvent from the process chamber. In some embodiments, the exhaust assembly comprises an exhaust pipe header equipped with a adjustable tube configured to target an area of the second photoresist layer based on a deviation from a predetermined thickness detected in the measured thickness of the first photoresist layer. In some embodiments, the adjustable tube is operable to rotate to align an exhaust flow with the area of the second photoresist layer.

In some embodiments, a system includes a hot plate, an exhaust pipe header, a metrology device, and a controller. The hot plate is located within a process chamber and configured to heat a first substrate held on the hot plate. The exhaust pipe header is located within the process chamber and above the hot plate, in which the exhaust pipe header comprises a plurality of adjustable exhaust tubes. The metrology device configured to capture a thickness profile of a first photoresist layer deposited on the first substrate. The controller is configured to generate a first adjustment parameter based on the captured thickness profile of the first photoresist layer, and initiate a first rotation of a first one of the adjustable exhaust tubes relative to the hot plate in response to the first adjustment parameter. The first rotation allows the first one of the adjustable exhaust tubes to target a first area of a second photoresist layer deposited on a second substrate held on the hot plate. In some embodiments, the controller is configured to generate a second adjustment parameter based on the captured thickness profile of the first photoresist layer, and initiate a second rotation of a second one of the adjustable exhaust tubes relative to the hot plate in response to the second adjustment parameter, the second rotation allows the second one of the adjustable exhaust tubes to target a second area of the second photoresist layer deposited on the second substrate held on the hot plate. In some embodiments, each of the exhaust pipe header further comprises a horizontal tube and a swivel joint connected between the horizontal tube and the adjustable exhaust tube, allowing the adjustable exhaust tube to pivot up to 360 degrees. In some embodiments, the exhaust pipe header further comprises a central vertical tube, and the adjustable exhaust tubes radially extend outward from the central vertical tube.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
coating a first photoresist material onto a first substrate positioned on a substrate stage within a process chamber of a coating apparatus, wherein the process chamber is in a first exhaust rate during the dispensing the first photoresist material;
measuring a thickness of the first photoresist material on the first substrate;
adjusting an exhaust efficiency within the process chamber through an exhaust assembly based on the measured thickness, wherein the adjustment regulates an evacuation of air and volatiles from the process chamber; and
coating a second photoresist material onto a second substrate positioned on the substrate stage, wherein the process chamber is in a second exhaust rate during the dispensing the second photoresist material.

2. The method of claim 1, wherein the second exhaust rate is higher than the first exhaust rate when the measured thickness of the first photoresist material exceeds a predetermined threshold.

3. The method of claim 1, wherein the second exhaust rate is lower than the first exhaust rate when the measured thickness of the first photoresist material is below a predetermined threshold.

4. The method of claim 1, wherein the step of adjusting the exhaust efficiency comprises:
comparing the measured thickness of the first photoresist material with a predetermined thickness; and
calculating the second exhaust rate from the first exhaust rate based on an outcome of the comparison.

5. The method of claim 1, further comprising:
recording the measured thickness of the first photoresist material in an archive database.

6. The method of claim 1, wherein the step of adjusting the exhaust efficiency comprises:
modifying an operation of a first regulator connected to a first exhaust pipe of the exhaust assembly.

7. The method of claim 6, wherein the first regulator comprises a first valve, and the step of adjusting the exhaust efficiency comprises setting a first valve flap of the first valve to a first orientation.

8. The method of claim 7, further comprising:
modifying an operation of a second regulator connected to a second exhaust pipe of the exhaust assembly, wherein the second regulator comprises a second valve, and the step of adjusting the exhaust efficiency comprises setting a second valve flap of the second valve to a second orientation different than the first orientation.

9. The method of claim 6, wherein the first regulator comprises a first fan, and the step of adjusting the exhaust efficiency comprises setting a first fan blade in the first fan to a first rotation speed.

10. The method of claim 9, further comprising:
modifying an operation of a second regulator connected to a second exhaust pipe of the exhaust assembly, wherein the second regulator comprises a second fan, and the step of adjusting the exhaust efficiency comprises setting a second fan blade in the second fan to a second rotation speed different than the first rotation speed.

11. A method, comprising:
positioning a first substrate on a temperature-controlled plate within a process chamber of a fabrication apparatus;
curing a first photoresist layer deposited on the first substrate using the temperature-controlled plate;
measuring a thickness of the cured first photoresist layer;
positioning a second substrate on the temperature-controlled plate;
after positioning the second substrate, adjusting an exhaust condition within the process chamber based on the measured thickness; and
curing a second photoresist layer deposited on the second substrate.

12. The method of claim 11, wherein the temperature-controlled plate comprises a heating function or cooling function based on a process requirement for the first and second photoresist layers.

13. The method of claim 11, further comprising:
before positioning the first substrate on the temperature-controlled plate, performing an exposure process on the first substrate, wherein the exposure process patterns the first photoresist layer deposited on the first substrate.

14. The method of claim 11, wherein the step of adjusting the exhaust condition comprises:
actuating an exhaust assembly to modify an evacuation rate of an evaporated solvent from the process chamber.

15. The method of claim 14, wherein the exhaust assembly comprises an exhaust pipe header equipped with an adjustable tube configured to target an area of the second photoresist layer based on a deviation from a predetermined thickness detected in the measured thickness of the first photoresist layer.

16. The method of claim 15, wherein the adjustable tube is operable to rotate to align an exhaust flow with the area of the second photoresist layer.

17. A system, comprising:
a hot plate located within a process chamber and configured to heat a first substrate held on the hot plate;
an exhaust pipe header located within the process chamber and above the hot plate, wherein the exhaust pipe header comprises a plurality of adjustable exhaust tubes;
a metrology device configured to capture a thickness profile of a first photoresist layer deposited on the first substrate; and
a controller configured to generate a first adjustment parameter based on the captured thickness profile of the first photoresist layer, and initiate a first rotation of a first one of the adjustable exhaust tubes relative to the hot plate in response to the first adjustment parameter, the first rotation allows the first one of the adjustable exhaust tubes to target a first area of a second photoresist layer deposited on a second substrate held on the hot plate.

18. The system of claim 17, wherein the controller is configured to generate a second adjustment parameter based on the captured thickness profile of the first photoresist layer, and initiate a second rotation of a second one of the adjustable exhaust tubes relative to the hot plate in response to the second adjustment parameter, the second rotation allows the second one of the adjustable exhaust tubes to target a second area of the second photoresist layer deposited on the second substrate held on the hot plate.

19. The system of claim 17, wherein each of the exhaust pipe header further comprises a horizontal tube and a swivel joint connected between the horizontal tube and the adjustable exhaust tube, allowing the adjustable exhaust tube to pivot up to 360 degrees.

20. The system of claim 17, wherein the exhaust pipe header further comprises a central vertical tube, and the adjustable exhaust tubes radially extend outward from the central vertical tube.
